(19) United States
(12) Patent Application Publication
(10) Pub. No.: US 2026/0114257 A1
(43) Pub. Date: Apr. 23, 2026

(54) SEMICONDUCTOR DEVICE WITH LENS REGION

(71) Applicant: SAMSUNG ELECTRONICS CO., LTD., Suwon-si (KR)

(72) Inventor: Woojin JIN, Suwon-si (KR)

(73) Assignee: SAMSUNG ELECTRONICS CO., LTD., Suwon-si (KR)

(21) Appl. No.: 19/094,243

(22) Filed: Mar. 28, 2025

(30) Foreign Application Priority Data
Nov. 27, 2024 (KR) 10-2024-0171589
Oct. 2, 2024 (KR) 10-2024-0134178

(51) Int. Cl. H01L 23/528; H01L 23/00

(52) U.S. Cl. CPC H10W 20/43; H10W 42/00

(57) ABSTRACT

A semiconductor device includes a semiconductor substrate, a plurality of standard cells disposed in a first direction and a second direction, a plurality of signal interconnections disposed in an upper insulating layer on the upper surface of the semiconductor substrate and coupled with the plurality of standard cells, and a plurality of power interconnections disposed on a lower surface of the semiconductor substrate and coupled with at least a portion of the plurality of standard cells. The first direction and the second direction are parallel to an upper surface of the semiconductor substrate. At least one target standard cell from among the plurality of standard cells includes a target pin. A lens region including only the upper insulating layer is disposed on at least a partial region of the target pin in a third direction perpendicular to the upper surface of the semiconductor substrate.

### CROSS-REFERENCE TO RELATED APPLICATIONS

This application claims benefit of priority under 35 U.S.C. § 119 to Korean Patent Application No. 10-2024-0171589, filed on November 27, 2024, and Korean Patent Application No. 10-2024-0134178, filed on October 2, 2024, in the Korean Intellectual Property Office, the disclosures of which are incorporated by reference herein in their entireties.

### BACKGROUND

### 1. Field

The present disclosure generally to a semiconductor devices, and more particularly, to a semiconductor device with a lens region.

### 2. Description of Related Art

A semiconductor device may include a plurality of semiconductor elements formed on a semiconductor substrate, and a plurality of interconnections connected to at least a portion of the plurality of semiconductor elements. For example, the plurality of interconnections may be disposed on one surface of the semiconductor substrate, and may include a plurality of power interconnections providing a transfer path for a power voltage, and/or a plurality of signal interconnections connected to the plurality of semiconductor elements providing a transfer path for a signal. Attempts to increase arrangement efficiency of the plurality of interconnections may include a semiconductor device having a structure in which a plurality of signal interconnections may be disposed on one surface of the semiconductor substrate, and a plurality of power interconnections may be disposed on the other surface. However, in such a structure, an optical signal and/or an electron beam signal for fault isolation may not reach one surface of the semiconductor substrate, and accordingly, fault isolation may not be able to be performed.

There exists a need for further improvements in semiconductor technology, as the need for efficiency of the plurality of interconnections may be constrained by a need to perform fault isolation. Improvements are presented herein. These improvements may also be applicable to other semiconductor technologies.

### SUMMARY

One or more example embodiments of the present disclosure provide a semiconductor device having a structure in which a plurality of signal interconnections are disposed on a first surface of a semiconductor substrate and a plurality of power interconnections are disposed on a second surface opposing the first surface, which may perform fault isolation.

According to an aspect of the present disclosure, a semiconductor device includes a semiconductor substrate, a plurality of standard cells disposed in a first direction and a second direction, a plurality of signal interconnections disposed in an upper insulating layer on the upper surface of the semiconductor substrate and coupled with the plurality of standard cells, and a plurality of power interconnections disposed on a lower surface of the semiconductor substrate and coupled with at least a portion of the plurality of standard cells. The first direction and the second direction are parallel to an upper surface of the semiconductor substrate. At least one target standard cell from among the plurality of standard cells includes a target pin. A lens region including only the upper insulating layer is disposed on at least a partial region of the target pin in a third direction perpendicular to the upper surface of the semiconductor substrate.

According to an aspect of the present disclosure, a semiconductor device includes a semiconductor substrate, a plurality of standard cells disposed in a first direction and a second direction, a plurality of signal interconnections disposed on the upper surface of the semiconductor substrate and coupled with the plurality of standard cells, a plurality of power interconnections disposed on a lower surface of the semiconductor substrate and coupled with at least a portion of the plurality of standard cells, and a plurality of dummy interconnections disposed on the upper surface of the semiconductor substrate and isolated from the plurality of standard cells. The first direction and the second direction are parallel to an upper surface of the semiconductor substrate. The plurality of standard cells include at least one target standard cell. A target pin is at least one of an input pin or an output pin of the at least one target standard cell. At least a partial region of the target pin at least partially overlaps a lens region optically exposing the target pin in a third direction perpendicular to the upper surface of the semiconductor substrate.

According to an aspect of the present disclosure, a semiconductor device includes a semiconductor substrate, an element region, a back-layer interconnection region, and a front-layer interconnection region. The element region includes a plurality of semiconductor elements formed on a first surface of the semiconductor substrate, and a plurality of contact structures coupled with the plurality of semiconductor elements. The back-layer interconnection region is disposed on a second surface of the semiconductor substrate opposing the first surface of the semiconductor substrate, and includes a plurality of power interconnections coupled with at least a first portion of the plurality of contact structures by via structures at least partially penetrating the semiconductor substrate. The front-layer interconnection region includes a plurality of signal interconnections coupled with at least a second portion of the plurality of contact structures, and a plurality of front-layer interconnection layers stacked on the first surface of the semiconductor substrate. The plurality of signal interconnections include at least one target pin. Each of at least a portion of the plurality of front-layer interconnection layers, positioned on the at least one target pin in a direction perpendicular to the first surface of the semiconductor substrate, includes a block region from which the plurality of signal interconnections are excluded.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1 is a diagram illustrating a process of manufacturing a semiconductor device, according to an example embodiment of the present disclosure;

FIGS. 2 and 3 are diagrams illustrating a semiconductor device, according to an example embodiment of the present disclosure;

FIG. 4 is a diagram illustrating a semiconductor device, according to an example embodiment of the present disclosure;

FIGS. 5 and 6 are diagrams illustrating a semiconductor device, according to an example embodiment of the present disclosure;

FIGS. 7 and 8 are diagrams illustrating circuits included in a semiconductor device, according to an example embodiment of the present disclosure;

FIGS. 9 and 10 are diagrams illustrating a semiconductor device, according to an example embodiment of the present disclosure;

FIGS. 11A to 11C are diagrams illustrating a lens region included in a semiconductor device, according to an example embodiment of the present disclosure;

FIGS. 12A to 12C are diagrams illustrating a lens region included in a semiconductor device, according to an example embodiment of the present disclosure;

FIGS. 13 and 14 are diagrams illustrating a process of designing a semiconductor device, according to an example embodiment of the present disclosure; and

FIGS. 15 and 16 are diagrams illustrating a process of designing a semiconductor device, according to an example embodiment of the present disclosure.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, and the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

It is to be understood that the specific order or hierarchy of blocks in the processes/flowcharts disclosed are an illustration of exemplary approaches. Based upon design preferences, it is understood that the specific order or hierarchy of blocks in the processes/flowcharts may be rearranged. Further, some blocks may be combined or omitted. The accompanying claims present elements of the various blocks in a sample order, and are not meant to be limited to the specific order or hierarchy presented.

In the present disclosure, the articles “a” and “an” are intended to include one or more items, and may be used interchangeably with “one or more.” Where only one item is intended, the term “one” or similar language is used. For example, the term “a processor” may refer to either a single processor or multiple processors. When a processor is described as carrying out an operation and the processor is referred to perform an additional operation, the multiple operations may be executed by either a single processor or any one or a combination of multiple processors.

As used herein, each of the terms “SiN”, “SiO”, “TaN”, “TiN”, “WN”, or the like may refer to a material made of elements included in each of the terms and is not a chemical formula representing a stoichiometric relationship.

Hereinafter, various embodiments of the present disclosure are described with reference to the accompanying drawings.

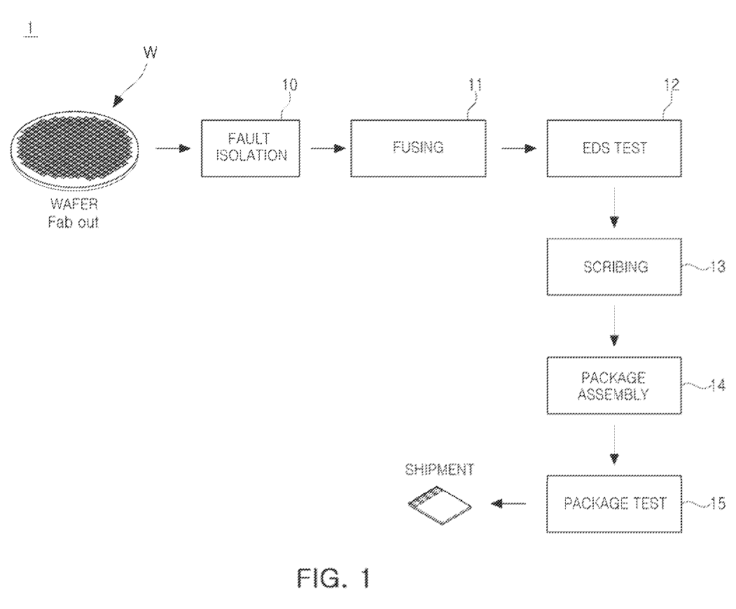

FIG. 1 is a diagram illustrating a process of manufacturing a semiconductor device, according to an example embodiment.

Referring to FIG. 1, a plurality of semiconductor dies may be manufactured by performing a manufacturing process 1 on a wafer W. The wafer W may include semiconductor dies and may be fab-out. In an embodiment, semiconductor dies included in the wafer W may provide the same type of semiconductor device. However, the present disclosure is not limited in this regard, and the wafer W may provide different semiconductor devices of different types.

As shown in FIG. 1, the manufacturing process 1 may include one or more semiconductor processes that may include a fault isolation operation 10, a fusing operation 11, an electrical die sorting (EDS) test 12, a scribing process 13, a package assembly process 14, and a package test 15.

When the wafer W is fab-out, the fault isolation operation 10 may be executed on the wafer W. The fault isolation operation 10 may refer to an operation to executed as an optical fault isolation operation and/or an electrical fault isolation operation. In the optical fault isolation operation, an optical signal may be applied to the wafer W, and in the electrical fault isolation operation, an electron beam (e.g., electrical) signal may be applied to the wafer W. The optical signal and/or the electron beam signal may be reflected from a target pin included in the semiconductor device. Consequently, by measuring a reflective signal generated by the optical signal and/or the electron beam signal applied to the wafer W, a fault present in the wafer W may be isolated.

When the fault isolation operation 10 is completed, the fusing operation 11 may be executed. The fusing operation 11 may include operations such as, but not limited to, storing data needed for customizing and/or operating the semiconductor device in fuse cells. When the fusing operation 11 is completed, the EDS test 12 may be performed. In an example embodiment, the EDS test 12 may include an EDS test performed multiple times under different temperature conditions. However, the present disclosure is not limited in this regard, and the EDS test may include other various tests. Depending on the results of the EDS test 12, the data stored in the fuse cells in the fusing operation 11 may be confirmed and/or may be changed.

When the EDS test 12 is completed, the scribing process 13 may be performed on the wafer W and semiconductor dies may be separated from the wafer W. Each of the semiconductor dies separated from the wafer W may be input into the package assembly process 14, and the package test 15 may be performed on the package produced in the package assembly process 14. Subsequent to the package test 15, the product (e.g., at least a portion of the semiconductor dies separated from the wafer W that may have successfully passed the package test 15) may be shipped.

The number and arrangement of operations and tests of the manufacturing process 1 shown in FIG. 1 are provided as an example. In practice, there may be additional operations and/or tests, fewer operations and/or tests, different operations and/or tests, or differently arranged operations and/or tests than those shown in FIG. 1. Furthermore, two (2) or more operations and/or tests shown in FIG. 1 may be implemented within a single operation and/or test, or a single operation and/or test shown in FIG. 1 may be implemented as multiple, distributed operations and/or tests.

For example, the manufacturing process 1 of manufacturing a plurality of semiconductor dies on the wafer W may include a process of forming a plurality of semiconductor elements on the wafer W, and/or a process of forming a plurality of interconnections connected to the plurality of semiconductor elements. For example, the process of forming a plurality of interconnections on the wafer W may include a process of forming a plurality of signal interconnections on a first surface of the wafer W, and/or a process of forming a plurality of power interconnections on a second surface of the wafer W, which may be different from the first surface.

The first surface and the second surface may oppose each other, and a plurality of semiconductor elements may be formed on at least one of the first surface and the second surface. For example, when the plurality of semiconductor elements are formed on the first surface, the plurality of power interconnections may be connected to the plurality of semiconductor elements by a through-via penetrating the wafer W. At least one power mesh connected to the plurality of power interconnections may be formed on the second surface.

In the wafer W having the structure described above, the fault isolation operation 10 may not be performed because an optical signal and an electron beam signal for performing the fault isolation operation 10 may be blocked. For example, a signal irradiated from the first surface side of the wafer W may be blocked by the plurality of signal interconnections on the second surface of the wafer W, and/or a signal irradiated from the second surface side of the wafer W may be blocked by the plurality of power interconnections on the first surface of the wafer W. Accordingly, the signal irradiated to perform the fault isolation operation 10 may not reach the target pin, and accordingly, the fault isolation operation 10 may not be performed.

In an example embodiment, in a structure in which interconnections are disposed on both the first surface and the second surface of the wafer W, a lens region in which interconnections are not disposed may be formed on the wafer W such that the fault isolation operation 10 may be performed. The lens region may be formed on the target pin on which the fault isolation operation 10 is performed, and only an insulating layer may be disposed without interconnections in at least a portion of the region defined on the target pin by the lens region.

In the fault isolation operation 10, an optical signal may be applied to the lens region. The optical signal may be incident to the lens region and may be reflected from the target pin, and a fault may be isolated by measuring a reflective signal discharged from the target pin. For example, the target pin may be an input pin and/or an output pin of a circuit such as, but not limited to, a flip-flop included in a scan chain circuit.

The lens region may be automatically defined during the process of designing the semiconductor die. An operation of designing the semiconductor die may include an operation of selecting at least a portion of standard cells from a library including standard cells and disposing and connecting the standard cells. In an example embodiment, target standard cells may be selected from among the standard cells, and a block region may be specified on a target pin included in each of the target standard cells, in which interconnections may not be disposed. During the process of disposing and/or connecting the standard cells, the interconnections may be disposed to avoid the block region, and accordingly, a lens region in which only an insulating layer is disposed without interconnections may be formed on the target pin.

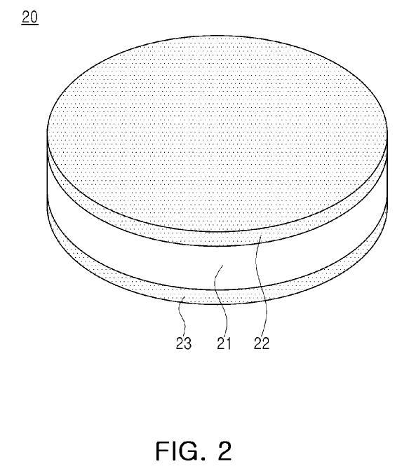

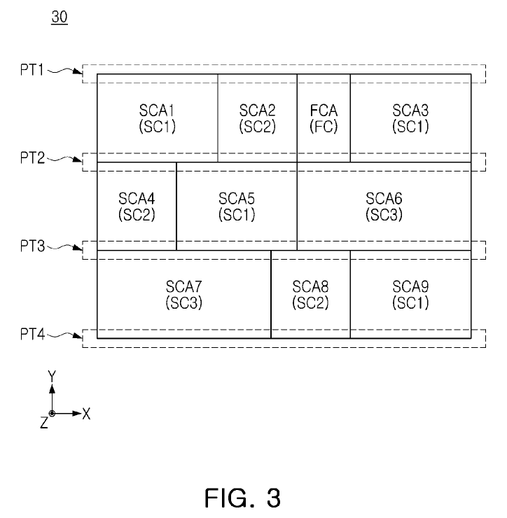

FIGS. 2 and 3 are diagrams illustrating a semiconductor device, according to an example embodiment.

As described above, the manufacturing process 1 of manufacturing a semiconductor device, according to an example embodiment, may include a process of forming interconnections on each of a first surface and a second surface provided as a semiconductor substrate. Referring to FIG. 2, a wafer 20, after the manufacturing process 1 is completed, may include a front-layer interconnection region 22 formed on a first surface of a semiconductor substrate 21, and a back-layer interconnection region 23 formed on a second surface of the semiconductor substrate 21 opposing the first surface.

In an example embodiment, the front-layer interconnection region 22 may include signal interconnections electrically connecting at least a portion of a plurality of semiconductor elements formed on the first surface of the semiconductor substrate 21 and providing a transfer path for voltage signals. The back-layer interconnection region 23 may include power interconnections supplying a power voltage to at least a portion of the plurality of semiconductor elements. The power interconnections may be electrically connected to at least a portion of the plurality of semiconductor elements by through-vias penetrating the semiconductor substrate 21. The wafer 20 may have a back side power distribution network (BSPDN) structure in which the power interconnections are disposed in the back-layer interconnection region 23.

The plurality of semiconductor elements formed on the first surface of the semiconductor substrate 21 may be included in a plurality of standard cells arranged in the first and second directions, which may be parallel to the first surface and intersecting each other. Each of the plurality of standard cells may include at least one semiconductor element arranged according to a layout predefined in a standard cell library. An operation of designing a semiconductor device implemented on the wafer 20 may include a disposing and routing operation of disposing and connecting the plurality of standard cells to a region of the wafer 20 other than a scribing region. In the disposing and routing operation, signal interconnections electrically connected to the plurality of standard cells may be disposed in the front-layer interconnection region 22, and/or power interconnections connected to at least a portion of the plurality of standard cells may be disposed in the back-layer interconnection region 23. However, the present disclosure is not limited in this regard, and the signal interconnections and/or the power interconnections may be disposed in various other arrangements without departing from the scope of the present disclosure.

FIG. 3 is a diagram illustrating a partial region of a semiconductor device 30. Referring to FIG. 3, the semiconductor device 30 may include a plurality of standard cell regions (e.g., a first standard cell region SCA1, a second standard cell region SCA2, a third standard cell region SCA3, a fourth standard cell region SCA4, a fifth standard cell region SCA5, a sixth standard cell region SCA6, a seventh standard cell region SCA7, an eighth standard cell region SCA8, and a ninth standard cell region SCA9) and at least one filler cell region FCA, arranged in the first direction (X-axis direction) and the second direction (Y-axis direction). Each of the first direction and the second direction may be parallel to an upper surface of the semiconductor substrate included in the semiconductor device 30.

A plurality of standard cells (e.g., a first standard cell SC1, a second standard cell SC2, and a third standard cell SC3) may be disposed in the plurality of first to ninth standard cell regions SCA1 to SCA9, and each of the plurality of first to third standard cells SC1 to SC3 may provide a circuit which may actually operate. At least a portion of the plurality of first to third standard cells SC1 to SC3 may be disposed in two or more regions among the plurality of first to ninth standard cell regions SCA1 to SCA9 in an overlapping manner. For example, the first standard cell SC1 may be disposed in the first standard cell region SCA1, the third standard cell region SCA3, the fifth standard cell region SCA5, and the ninth standard cell region SCA9. As another example, the second standard cell SC2 may be disposed in the second standard cell region SCA2, the fourth standard cell region SCA4, and the eighth standard cell region SCA8. As another example, the third standard cell SC3 may be disposed in the sixth standard cell region SCA6, and the seventh standard cell region SCA7. The filler cell FC may be disposed in the filler cell region FCA, and at least one semiconductor element included in the filler cell FC may not be involved in the actual operation of the semiconductor device 30.

Although FIG. 3 depicts the semiconductor device 30 as having nine (9) standard cell regions and three (3) standard cells, the present disclosure is not limited in this regard. That is, the semiconductor device 30 may include less standard cell regions (e.g., less than nine (9)), more standard cell regions (e.g., greater than nine (9)), less standard cells (e.g., less than three (3)), and/or more standard cells (e.g., more than three (3)). In addition, the arrangement of the standard cells and/or the standard cell regions on the semiconductor device 30 may be different from the example arrangement depicted in FIG. 3, without departing from the scope of the present disclosure.

Referring to FIG. 3, a plurality of power tracks (e.g., a first power track PT1, a second power track PT2, a third power track PT3, and a fourth power track PT4) extending in the first direction and arranged in the second direction may be defined between the plurality of first to ninth standard cell regions SCA1 to SCA9. The plurality of first to third standard cells SC1 to SC3 may have a predetermined cell height (cell height) in the second direction, and the cell height may be determined by a distance between the plurality of first to fourth power tracks PT1 to PT4 adjacent to each other.

In an embodiment, the plurality of first to fourth power tracks PT1to PT4 may be and/or may include a region allocated as an arrangement space of power interconnections for transferring power voltages. However, in a structure in which power interconnections are disposed in the back-layer interconnection region 23 of the semiconductor substrate 21, power interconnections may not be disposed along the plurality of first to fourth power tracks PT1 to PT4. The plurality of first to fourth power tracks PT1 to PT4 may be allocated as a region disposing signal interconnections electrically connected to a plurality of first to third standard cells SC1 to SC3. Accordingly, a design freedom of the signal interconnections may be improved and/or an integration density of the semiconductor device 30 may be improved, when compared to related semiconductor devices. For example, the plurality of signal interconnections may include lowermost interconnections positioned at a level closest to the semiconductor substrate, and at least a portion of the lowermost interconnections may be disposed in a region defined by the plurality of first to fourth power tracks PT1 to PT4.

At least a portion of the plurality of first to third standard cells SC1 to SC3 may be selected as a target standard cell to be monitored for fault isolation after a wafer 20 including a semiconductor device 30 is fab-out. In an example embodiment, the target standard cell may include an input pin for receiving an input signal from another standard cell, and/or an output pin for sending an output signal to another standard cell. A monitoring operation of isolating a fault by measuring an input signal and/or an output signal may be executed after the wafer 20 is fab-out. For example, the target standard cell may provide a sequential logic circuit operating in synchronization with a clock signal.

However, in a structure in which signal interconnections are disposed on the front-layer interconnection region 22 of the semiconductor substrate 21 and power interconnections are disposed on the back-layer interconnection region 23 of the semiconductor substrate 21, as described with reference to FIG. 2, an optical signal and/or an electron beam signal for fault isolation may not reach the input pin and/or the output pin. Accordingly, a monitoring operation for isolating a fault may not be executed after the wafer 20 is fab-out.

In an example embodiment, prior to an operation of disposing and routing standard cells, a target standard cell may be pre-selected, and a block region in which signal interconnections and dummy interconnections are not disposed may be defined on a target pin included in the target standard cell. The block region may be defined for each front-layer interconnection layer disposed on the target pin. A lens region in which only an insulating layer is disposed without interconnections may be disposed on the target pin by the block region defined for each front-layer interconnection layer, and an input signal and/or an output signal through the target pin may be measured through the lens region. Accordingly, as for a semiconductor device 30 having a structure in which the entirety of interconnections are disposed on the front-layer interconnection region 22 and back-layer interconnection region 23 of the semiconductor substrate 21, a monitoring operation of isolating a fault on the target pin may be performed after the wafer 20 is fab-out.

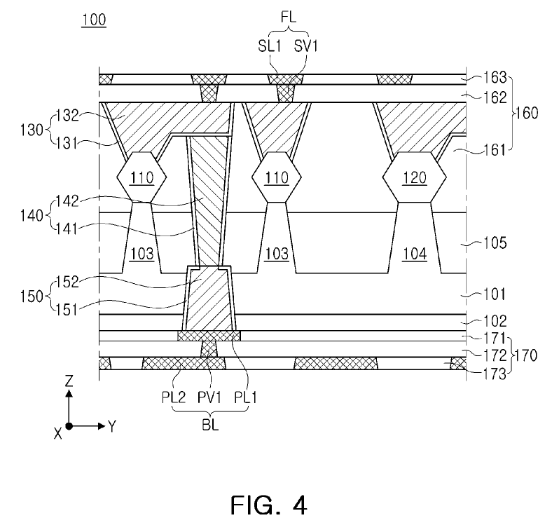

FIG. 4 is a diagram illustrating a semiconductor device, according to an example embodiment. A semiconductor device 100 of FIG. 4 may include and/or may be similar in many respects to the semiconductor device 30 described above with reference to FIG. 3, and may include additional features not mentioned above. Consequently, repeated descriptions of the semiconductor device 100 described above with reference to FIG. 3 may be omitted for the sake of brevity.

Referring to FIG. 4, the semiconductor device 100, according to an example embodiment, may include a semiconductor substrate 101, a plurality of active patterns (e.g., first active patterns 103 and second active patterns 104) formed on an upper surface of the substrate 101 and providing an active region, an element isolation layer 105 surrounding the plurality of first and second active patterns 103 and 104, and a plurality of source/drain regions (e.g., first source/drain regions 110 and second source/drain regions 120) extending from the plurality of first and second active patterns 103 and 104. In an embodiment, a gate structure may be disposed between the plurality of first and second source/drain regions 110 and 120 adjacent to each other in the first direction (X-axis direction). For example, the gate structure may extend in the second direction (Y-axis direction).

A plurality of upper insulating layers 160 (e.g., a first upper insulating layer 161, a second upper insulating layer 162, and a third upper insulating layer 163) may be disposed on the element isolation layer 105. The plurality of first and second source/drain regions 110 and 120 and a plurality of contact structures 130 connected to the plurality of first and second source/drain regions 110 and 120 may be disposed in the first upper insulating layer 161. The plurality of contact structures 130 may include a barrier layer 131 and a conductive layer 132. For example, the barrier layer 131 may be formed of a metal nitride such as, but not limited to, titanium nitride (TiN), tantalum nitride (TaN), tungsten nitride (WN), or the like, and the conductive layer 132 may be formed of a metal material such as, but not limited to, aluminum (Al), tungsten (W), molybdenum (Mo), or the like. A front-layer interconnection region FL including a first signal via SV1 and a first signal interconnection SL1 may be disposed in the second upper insulating layer 162 and the third upper insulating layer 163.

At least a portion of the plurality of first and second source/drain regions 110 and 120 may be electrically connected to a first through-structure 140 in the first upper insulating layer 161. The first through-structure 140 may include a first through-insulating layer 141 and a first through-conductive layer 142. The first through-insulating layer 141 may be formed of an insulating material such as, but not limited to, silicon oxide (SiO), silicon nitride (SiN), or the like, and the first through-conductive layer 142 may be formed of a conductive material, such as, but not limited to, copper (Cu), gold (Au), silver (Ag), nickel (Ni), tungsten (W), aluminum (Al), or the like.

The first through-structure 140 may be connected to a second through-structure 150 penetrating the semiconductor substrate 101. The second through-structure 150 may include a second through-insulating layer 151 and a second through-conductive layer 152. The second through-conductive layer 152 and the semiconductor substrate 101 may be electrically isolated from each other by the second through-insulating layer 151. The second through-structure 150 may be formed to penetrate the substrate insulating layer 102 disposed on a lower surface of the semiconductor substrate 101. In example embodiments, the first through-structure 140 and the second through-structure 150 may be formed as an integrated through-structure. For example, a single through-structure may extend from the substrate insulating layer 102 to the plurality of first and second source/drain regions 110 and 120.

A plurality of lower insulating layers 170 (e.g., a first lower insulating layer 171, a second lower insulating layer 172, and a third lower insulating layer 173) may be disposed on the substrate insulating layer 102. A back-layer interconnection region BL including a first power interconnection PL1, a first power via PV1, and a second power interconnection PL2, electrically connected to the second through-structure 150, may be disposed in the plurality of lower insulating layers 170. Accordingly, signal interconnections may be disposed on an upper surface of the semiconductor substrate 101, and power interconnections may be disposed on a lower surface of the semiconductor substrate 101.

As described with reference to FIG. 4, in a semiconductor device 100 having a structure in which signal interconnections are disposed on an upper surface of the semiconductor substrate 101, and power interconnections are disposed on a lower surface of the semiconductor substrate 101, it may be difficult to execute a monitoring operation of isolating a fault after the wafer is fab-out. In an embodiment, the monitoring operation for fault isolation may be performed by irradiating an optical signal and/or an electron beam signal to a target pin connected to the plurality of first and second source/drain regions 110 and 120 and/or the gate structure, and measuring a signal reflected from the target pin. Since the front-layer interconnection region FL connected to the target pin may be shielded by other signal interconnections and/or dummy interconnections on the upper surface of the semiconductor substrate 101 and by power interconnections on the lower surface of the semiconductor substrate 101, the optical signal and/or the electron beam signal may not reach the target pin.

In an example embodiment, by disposing a lens region in which the signal interconnection and the dummy interconnection are not disposed on the target pin, a monitoring operation of a target pin included in the semiconductor device 100 may be performed after the wafer is fab-out. The lens region may be formed by defining a block region in which the signal interconnection and the dummy interconnection may not be disposed, and for example, only an insulating layer may be disposed in the lens region. Accordingly, fault isolation for a target standard cell including the target pin may be performed by applying an optical signal and/or an electron beam signal to the target pin through the lens region and measuring a signal reflected from the target pin.

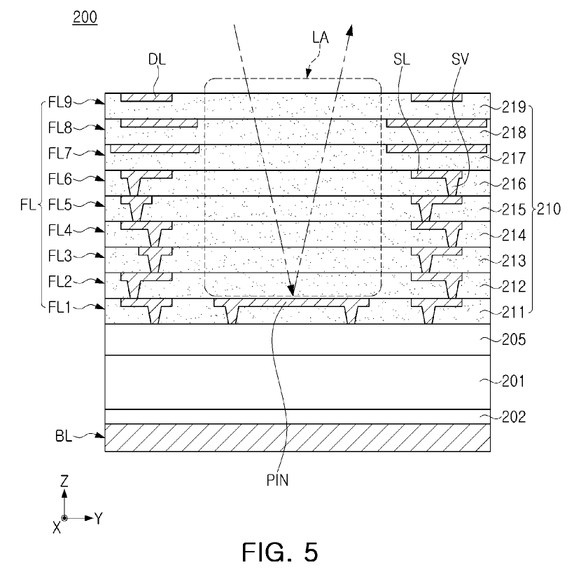

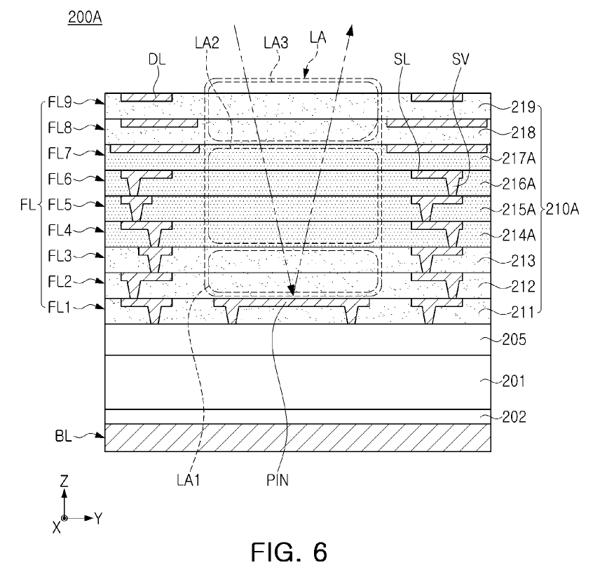

FIGS. 5 and 6 are diagrams illustrating a semiconductor device, according to an example embodiment. A semiconductor device 200 of FIG. 5 and a semiconductor device 200A of FIG. 6 may include and/or may be similar in many respects to the semiconductor device 30 and the semiconductor device 100 described above with reference to FIGS. 3 and 4, and may include additional features not mentioned above. Consequently, repeated descriptions of the semiconductor device 200 and the semiconductor device 200A described above with reference to FIGS. 3 and 4 may be omitted for the sake of brevity.

Referring to FIG. 5, the semiconductor device 200, according to an example embodiment, may include a semiconductor substrate 201, a substrate insulating layer 202, an element region 205, a front-layer interconnection region FL, and a back-layer interconnection region BL. The element region 205 and the front-layer interconnection region FL may be disposed on a first surface of the semiconductor substrate 201, and the substrate insulating layer 202 and the back-layer interconnection region BL may be disposed on a second surface of the semiconductor substrate 201 opposing the first surface. Each of the first surface and the second surface of the semiconductor substrate 201 may be parallel to the first direction (X-axis direction) and the second direction (Y-axis direction).

A plurality of semiconductor elements may be disposed in the element region 205. For example, the element region 205 may include a plurality of semiconductor elements, contact structures connected to the plurality of semiconductor elements, and an insulating layer. The plurality of semiconductor elements and the contact structures included in the element region 205 may be disposed according to a layout of each of the plurality of standard cells arranged in the first direction and the second direction during the process of designing the semiconductor device 200.

The contact structures included in the element region 205 may be electrically connected to signal vias SV and signal interconnections SL included in the front-layer interconnection region FL. The front-layer interconnection region FL may include a plurality of front-layer interconnection layers (e.g., a first front-layer interconnection layer FL1, a second front-layer interconnection layer FL2, a third front-layer interconnection layer FL3, a fourth front-layer interconnection layer FL4, a fifth front-layer interconnection layer FL5, a sixth front-layer interconnection layer FL6, a seventh front-layer interconnection layer FL7, an eighth front-layer interconnection layer FL8, a ninth front-layer interconnection layer FL9) stacked in the third direction (Z-axis direction) perpendicular to the first surface of the semiconductor substrate 201. The signal vias SV, the signal interconnections SL, and the dummy interconnections DL included in the plurality of first to ninth front-layer interconnection layers FL1 to FL9 may be disposed in a plurality of upper insulating layers 210 (e.g., a first upper insulating layer 211, a second upper insulating layer 212, a third upper insulating layer 213, a fourth upper insulating layer 214, a fifth upper insulating layer 215, a sixth upper insulating layer 216, a seventh upper insulating layer 217, an eighth upper insulating layer 218, a ninth upper insulating layer 219). In an example embodiment, each of the plurality of upper insulating layers 210 may include a low-κ material.

The back-layer interconnection region BL may include a power mesh and a power interconnection for supplying a power voltage to the plurality of semiconductor elements included in the element region 205. The power interconnection of the back-layer interconnection region BL may be electrically isolated from the semiconductor substrate 201 by the substrate insulating layer 202 and may extend to the element region 205 by penetrating the semiconductor substrate 201 and the substrate insulating layer 202.

Continuing to refer to FIG. 5, at least a portion of the plurality of semiconductor elements included in the element region 205 may be connected to a target pin PIN. For example, the target pin PIN may be included in at least one target standard cell from among the plurality of standard cells, and may be a pin for receiving an input signal or outputting an output signal from a circuit implemented as the target standard cell. In an example embodiment, the target standard cell including the target pin PIN may provide a sequential logic circuit operating in synchronization with a clock signal.

In a semiconductor device 200, according to an example embodiment illustrated in FIG. 5, a front-layer interconnection region FL may be disposed on a first surface of a semiconductor substrate 201, and a back-layer interconnection region BL may be disposed on a second surface of the semiconductor substrate 201. In an example embodiment, after a wafer including the semiconductor device 200 is fab-out, a lens region LA may be formed in the front-layer interconnection region FL to perform an operation of performing fault isolation by irradiating an optical signal and an electron beam signal to the target pin PIN. The lens region LA may be disposed on the target pin PIN, and the signal interconnection SL, the signal vias SV, and the dummy line DL may not be disposed in the lens region LA. At least a partial region of the target pin PIN may be optically exposed by the lens region LA.

Continuing to refer to FIG. 5, only the second to ninth upper insulating layers 212 to 219 may be disposed in the lens region LA. For example, an optical signal (represented by the dashed arrows in FIG. 5) incident from the upper surface of the ninth upper insulating layer 219 disposed at an uppermost end in the third direction may reach the target pin PIN through the lens region LA, and a reflective signal generated by the optical signal being reflected from the target pin PIN may be discharged to the outside through the lens region LA. Accordingly, after a wafer including the semiconductor device 200 is fab-out, a monitoring operation of isolating a fault may be executed by irradiating the optical signal to the lens region LA and isolating the reflective signal discharged from the lens region LA after being reflected from the target pin PIN.

A semiconductor device 200A, according to an example embodiment illustrated in FIG. 6 may have a structure similar to the structure of the semiconductor device 200, according to an example embodiment described with reference to FIG. 5. For example, the semiconductor device 200A may include a semiconductor substrate 201, an element region 205, a substrate insulating layer 202, a front-layer interconnection region FL, and a back-layer interconnection region BL. The front-layer interconnection region FL may include the plurality of first to ninth front-layer interconnection layers FL1 to FL9, signal vias SV, signal interconnections SL, and dummy interconnections DL may be disposed in a plurality of upper insulating layers 210A (e.g., a first upper insulating layer 211, a second upper insulating layer 212, a third upper insulating layer 213, a fourth upper insulating layer 214A, a fifth upper insulating layer 215A, a sixth upper insulating layer 216A, a seventh upper insulating layer 217A, an eighth upper insulating layer 218, a ninth upper insulating layer 219).

Referring to FIG. 6, a portion of the plurality of upper insulating layers 210A may be formed of different materials. For example, the first to third upper insulating layers 211 to 213, the eighth upper insulating layer, and the ninth upper insulating layer 219 may be formed of a low-κ material, and the fourth to seventh upper insulating layers 214A to 217A may be formed of an ultra-low-κ material having a permittivity lower than that of the low-κ material. In an example embodiment, the ultra-low-κ material may be a material having a dielectric constant lower than 2.5.

Accordingly, the lens region LA may include a plurality of lens layers (e.g., a first lens layer LAL1, a second lens layer LAL2, and a third lens layer LAL3) stacked in the third direction and including different materials. The first lens layer LAL1 may be a region disposed on the target pin PIN on the first surface of the semiconductor substrate 201, and the second lens layer LAL2 may be a region stacked on the first lens layer LAL1 in the third direction. A permittivity of the first lens layer LAL1 may be higher than a permittivity of the second lens layer LAL2. In addition, the lens region LA may include a third lens layer LAL3 stacked on the second lens layer LAL2 in the third direction, and a permittivity of the third lens layer LAL3 may be higher than the permittivity of the second lens layer LAL2.

However, the stack structure of the lens region LA may be varied in example embodiments and is not limited to the example embodiments described with reference to FIGS. 5 and 6. For example, the lens region LA may be stacked in the third direction and may include two (2) lens layers having different permittivity, or may include four (4) or more lens layers.

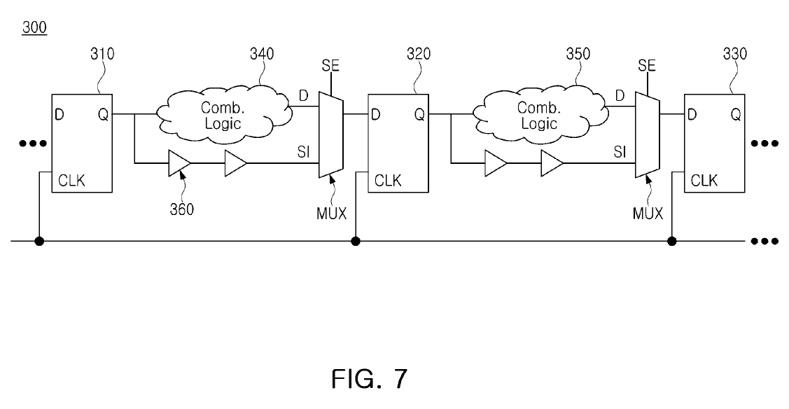

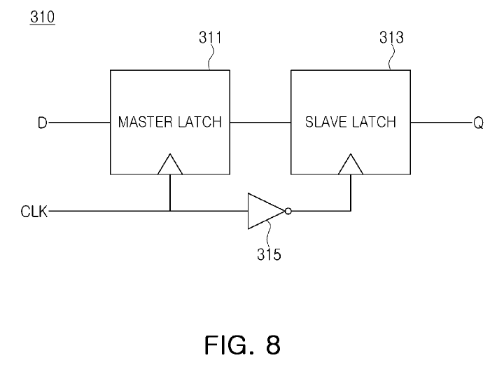

FIGS. 7 and 8 are diagrams illustrating circuits included in a semiconductor device, according to an example embodiment. A semiconductor device 300 of FIG. 7 may include and/or may be similar in many respects to the semiconductor device 30, the semiconductor device 100, the semiconductor device 200, and the semiconductor device 200A described above with reference to FIGS. 3 to 6, and may include additional features not mentioned above. Consequently, repeated descriptions of the semiconductor device 300 described above with reference to FIGS. 3 to 6 may be omitted for the sake of brevity.

Referring to FIG. 7, a semiconductor device 300, according to an example embodiment, may include a plurality of sequential logic circuits (e.g., a first sequential logic circuit 310, a second sequential logic circuit 320, and a third sequential logic circuit 330), a plurality of combinational logic circuits (e.g., a first combinational logic circuit 340 and a second combinational logic circuit 350), and a plurality of buffers 360. In an example embodiment illustrated in FIG. 7, each of the plurality of first to third sequential logic circuits 310 to 330 may be a D-flip-flop for ease of description. However, the present disclosure is not limited in this regard, and the plurality of first to third sequential logic circuits may be and/or may include same or different circuits from each other, and/or may include various other types of circuits.

Referring to FIG. 7, a multiplexer MUX may be connected to an input terminal of each of the first to third D-flip-flops 310 to 330. The multiplexer MUX may select one of a data input signal D and a scan input signal SI in response to a scan enable signal SE and may input the signal to the corresponding D-flip-flop. For example, when a normal operation is executed, the data input signal D may be selected by the scan enable signal SE, and when a scan shift operation is executed, the scan input signal SI may be selected by the scan enable signal SE. As another example, a circuit, according to an example embodiment illustrated in FIG. 7, may operate as a scan chain circuit included in the semiconductor device 300.

Each of the first to third D-flip-flops 310 to 330 may operate in synchronization with the clock signal CLK, and may latch a signal input to a rising edge of the clock signal CLK and may output the signal as an output signal Q, for example. Each of the first and second combinational logic circuits 340 and 350 may process the output signal Q of the D-flip-flop and may generate a data input signal D of the subsequent D-flip-flop. The plurality of buffers 360 may buffer the output signal Q of the D-flip-flop and may provide the signal as a scan input signal SI to a multiplexer MUX connected to an input terminal of the subsequent D-flip-flop.

FIG. 8 is a block diagram illustrating an exemplary structure of a first D-flip-flop 310 illustrated in FIG. 7. The first D-flip-flop 310 may include a master latch 311, a slave latch 313, and an inverter 315. The master latch 311 may operate in synchronization with a rising edge of the clock signal CLK, and the slave latch 313 may operate in synchronization with the rising edge of the clock signal CLK of which a phase is inverted by the inverter 315.

The master latch 311 and the slave latch 313 may receive a data input signal D from an external entity and may output an output signal Q. For example, a multiplexer MUX may be connected to the input terminal of the first D-flip-flop 310, and the master latch 311 may receive one of the signals output by a combinational logic circuit connected to a front end, or the signals output by another D-flip-flop connected to a front end as a data input signal D.

Each of the master latch 311 and the slave latch 313 may be implemented with various architectures. In an example embodiment, each of the master latch 311 and the slave latch 313 may be implemented as a transmission gate circuit and two (2) inverter circuits, and in this case, one of the two (2) inverter circuits may be a tri-state inverter circuit.

In order to execute a monitoring operation of isolating a fault of the semiconductor device 300 after the wafer including the semiconductor device 300 is fab-out, at least one of the input pins or the output pins included in each of the first to third sequential logic circuits 310 to 330 may be determined as a target pin for fault isolation. For example, in a D-flip-flop, one of the input pins receiving the scan input signal SI or the output pins outputting the output signal Q may be determined as a target pin. However, when the semiconductor device 300 has a BSPDN structure as described above, since the interconnection region is disposed on both an upper surface and a lower surface of the semiconductor substrate, an optical signal, and an electron beam signal may not be irradiated to the target pin.

In an example embodiment, by defining a lens region in which only an insulating layer is disposed without interconnection on the target pin, a monitoring operation for fault isolation may be performed after the wafer is fab-out with respect to the semiconductor device 300 manufactured as a wafer having a BSPDN structure. The lens region may be disposed on the target pin by defining a block region in which the interconnection may not be disposed in the target standard cell including the target pin during the process of designing the semiconductor device 300.

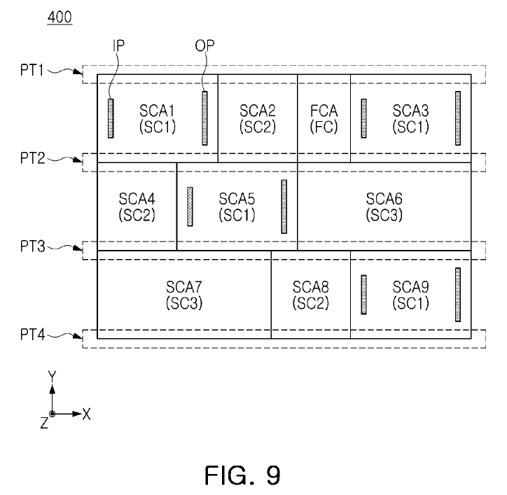

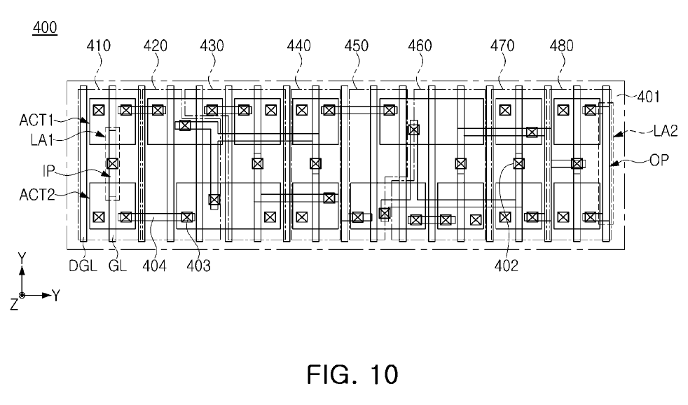

FIGS. 9 and 10 are diagrams illustrating a semiconductor device, according to an example embodiment.

FIG. 9 is a diagram illustrating a partial region of a semiconductor device 400. The semiconductor device 400 of FIG. 9 may include and/or may be similar in many respects to the semiconductor device 30, the semiconductor device 100, the semiconductor device 200, the semiconductor device 200A, and the semiconductor device 300 described above with reference to FIGS. 3 to 7, and may include additional features not mentioned above. Consequently, repeated descriptions of the semiconductor device 400 described above with reference to FIGS. 3 to 7 may be omitted for the sake of brevity.

Referring to FIG. 9, the semiconductor device 400 may include a plurality of first to third standard cells SC1 to SC3 and at least one filler cell FC arranged in the first direction (X-axis direction) and the second direction (Y-axis direction). The plurality of first to third standard cells SC1 to SC3 may be disposed in a plurality of first to ninth standard cell regions SCA1 to SCA9, and the filler cell FC may be disposed in a filler cell region FCA.

In an example embodiment illustrated in FIG. 9, the first standard cell SC1 may provide a sequential logic circuit (e.g., a D-flip-flop), as described above with reference to FIGS. 7 and 8. The first standard cell SC1 may include an input pin IP that may correspond to an input terminal of the D-flip-flop, and an output pin OP that may correspond to an output terminal of the D-flip-flop. The first standard cell SC1 disposed in each of the different standard cell regions may have the same layout, and accordingly, the input pin IP and the output pin OP may be disposed in a predetermined position.

Each of the input pin IP and the output pin OP may be disposed in a signal interconnection region on a first surface of the semiconductor substrate in which a plurality of semiconductor elements are formed. The signal interconnection region may include a plurality of signal interconnection layers stacked on the first surface of the semiconductor substrate, and each of the input pin IP and the output pin OP may be disposed in at least one of the plurality of signal interconnection layers. For example, the input pin IP and the output pin OP of the first standard cell SC may be disposed in the same signal interconnection layer, and/or the input pin IP and the output pin OP may be disposed in different signal interconnection layers.

Considering delay characteristics of the input signal received by the input pin IP and the output signal outputted by the output pin OP, each of the input pin IP and the output pin OP may not extend to an uppermost end signal interconnection layer among the plurality of signal interconnection layers. Accordingly, in the state in which the wafer is fab-out, at least one signal interconnection and/or dummy interconnection disposed in the signal interconnection layer may be positioned on the input pin IP and the output pin OP.

In a structure in which both the signal interconnections and the power interconnections are disposed on the first surface of the semiconductor substrate, the signal received by the first standard cell SC1 at the input pin IP and/or the signal outputted to the first standard cell SC1 output pin OP may be measured by irradiating the second surface opposing the first surface of the semiconductor substrate with an optical signal and an electron beam signal. Accordingly, a monitoring operation for fault isolation may be performed after the wafer is fab-out. In a structure in which signal interconnections are disposed on the first surface of the semiconductor substrate and power interconnections are disposed on the second surface, an optical signal and an electron beam signal irradiated to the second surface of the wafer may not reach the input pin IP and the output pin OP due to power interconnections and power mesh formed on the second surface.

In an example embodiment, prior to an operation of disposing and connecting a plurality of first to third standard cells SC1 to SC3, a target standard cell having a target pin on which a monitoring operation of isolating a fault is to be performed may be selected in advance. As for the target standard cell, a block region may be defined such that signal interconnections and dummy interconnections are not disposed on the target pin. The block region may be defined for the entirety of front-layer interconnection layers stacked on the target pin, and accordingly, a lens region including only an insulating layer without interconnections may be disposed on at least a partial region of the target pin. The monitoring operation for fault isolation may be performed by applying an optical signal to the target pin through the lens region and measuring a signal reflected from the target pin.

FIG. 10 is a diagram illustrating an example layout of a first standard cell SC1 included in a semiconductor device 400. Referring to FIG. 10, the first standard cell SC1 may provide a D-flip-flop, which is a sequential logic circuit, and may include gate structures GL and dummy gate structures DGL disposed on a first surface of a semiconductor substrate 401.

The gate structures GL and the dummy gate structures DGL may be arranged in the first direction (X-axis direction), may extend in the second direction (Y-axis direction), and each of the gate structures GL may intersect at least one active region (e.g., a first active region ACT1 or a second active region ACT2). In an example embodiment, the first active region ACT1 may be doped with N-type impurities, and the second active region ACT2 may be doped with P-type impurities. The gate structures GL and the first and second active regions ACT1 and ACT2 may be connected to the contact structures (e.g., a first contact structure 402 and a second contact structure 403) and a plurality of signal interconnections 404 and may provide various circuits.

In an example embodiment, a D-flip-flop implemented as a first standard cell SC1 may include a master latch and a slave latch, and the master latch and the slave latch may include transmission gates (e.g., a first transmission gate 420 and a second transmission gate 450), first inverters (e.g., a left first inverter 430 and a right first inverter 460) and second inverters (e.g., a left second inverter 440 and a right second inverter 470), respectively. An input inverter 410 may be connected to an input terminal of the master latch, and an output inverter 480 may be connected to an output terminal of the slave latch. The gate structure GL of the input inverter 410 may be electrically connected to the input pin IP of the first standard cell SC1, and the first and second active regions ACT1 and ACT2 providing an output terminal of the output inverter 480 may be electrically connected to the output pin OP.

As shown in FIG. 10, the first lens region LA1 may be disposed on the input pin IP, and the second lens region LA2 may be disposed on the output pin OP. As described above, each of the first lens region LA1 and the second lens region LA2 may include only insulating layers without a signal interconnection and a dummy interconnection. The first lens region LA1 may have an area smaller than an area of the input pin IP, and the second lens region LA2 may have a substantially similar and/or the same area as an area of the output pin OP. However, the present disclosure is not limited thereto.

In an embodiment, widths of the first lens region LA1 and the second lens region LA2 in the first direction and the second direction may be determined in a range necessary to irradiate optical signals to the input pin IP and the output pin OP for fault isolation. For example, the first lens region LA1 may have a width of tens to hundreds of nanometers (nm) in each of the first direction and the second direction. As another example, the first lens region LA1 may have a width of 20 nm in the first direction and a width of 100 nm in the second direction.

In an example embodiment, a shape of the first lens region LA1 may correspond to a shape of the input pin IP, and a shape of the second lens region LA2 may correspond to a shape of the output pin OP. The first lens region LA1 may have a greater width in the second direction than in the first direction, similarly to the input pin IP.

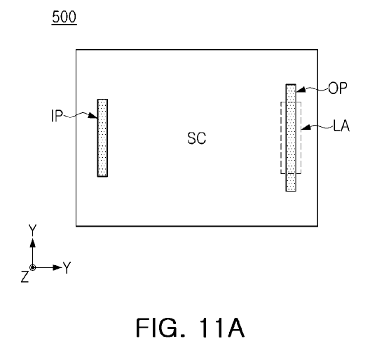

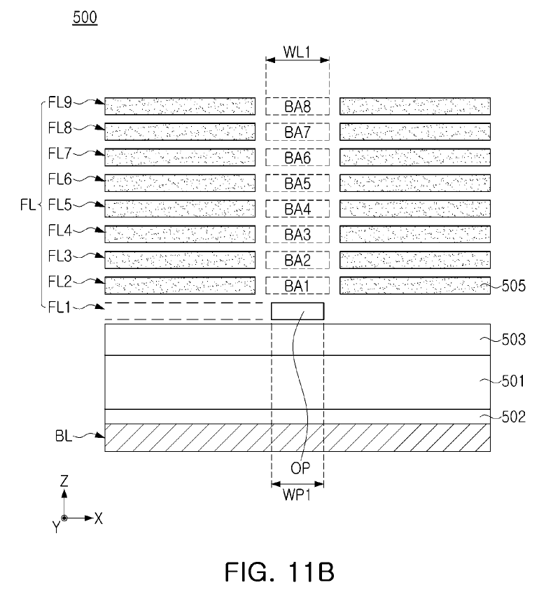

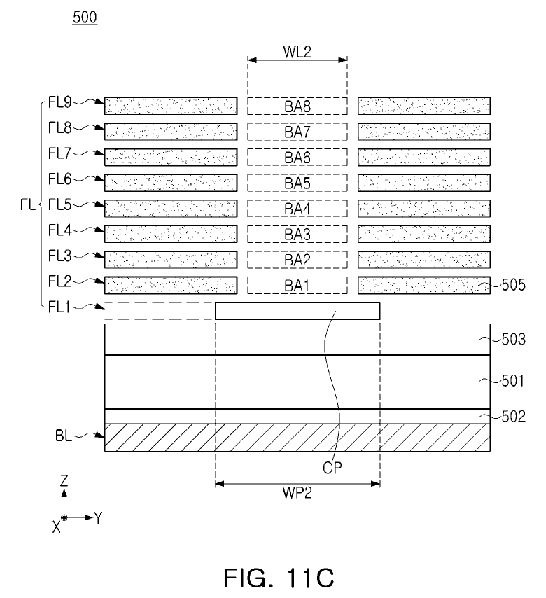

FIGS. 11A to 11C are diagrams illustrating a lens region included in a semiconductor device, according to an example embodiment. A semiconductor device 500 of FIG. 11A may include and/or may be similar in many respects to the semiconductor device 30, the semiconductor device 100, the semiconductor device 200, the semiconductor device 200A, the semiconductor device 300, and the semiconductor device 400 described above with reference to FIGS. 3 to 9, and may include additional features not mentioned above. Consequently, repeated descriptions of the semiconductor device 500 described above with reference to FIGS. 3 to 9 may be omitted for the sake of brevity.

Referring to FIG. 11A, the semiconductor device 500, according to an example embodiment, may include a standard cell SC. After a wafer including the semiconductor device 500 is fab-out, when the standard cell SC is selected as a target standard cell for isolating a fault, a lens region LA for irradiating an optical signal may be formed in the standard cell SC. In an example embodiment, the lens region LA may be disposed on an output pin OP selected as a target pin.

FIG. 11B is a cross-sectional diagram illustrating the lens region LA in the first direction (X-axis direction), and FIG. 11C is a cross-sectional diagram illustrating the lens region LA in the second direction (Y-axis direction). Referring to FIGS. 11B and 11C, the semiconductor device 500 may include a semiconductor substrate 501, an element region 503, a substrate insulating layer 502, a front-layer interconnection region FL, and a back-layer interconnection region BL. A plurality of semiconductor elements and contact structures may be disposed in the element region 503 defined on a first surface of the semiconductor substrate 501.

A substrate insulating layer 502 and a back-layer interconnection region BL may be disposed on a second surface of the semiconductor substrate 501, and the back-layer interconnection region BL may include power interconnections and a power mesh. The power interconnections may be connected to at least a portion of the plurality of semiconductor elements disposed in the element region 503 through a via structure penetrating the substrate insulating layer 502 and the semiconductor substrate 501.

The front-layer interconnection region FL above the element region 503 may include a plurality of front-layer interconnection layers (e.g., a first front-layer interconnection layer FL1, a second front-layer interconnection layer FL2, a third front-layer interconnection layer FL3, a fourth front-layer interconnection layer FL4, a fifth front-layer interconnection layer FL5, a sixth front-layer interconnection layer FL6, a seventh front-layer interconnection layer FL7, an eighth front-layer interconnection layer FL8, a ninth front-layer interconnection layer FL9), and the output pin OP may be disposed in the first front-layer interconnection layer FL1. However, an example embodiment thereof is not limited thereto, and the output pin OP may be disposed in another front-layer interconnection layer. A plurality of block regions (e.g., a first block region BA1, a second block region BA2, a third block region BA3, a fourth block region BA4, a five block region BA5, a sixth block region BA6, a seventh block region BA7, and an eighth block region BA8) may be defined in the other second to ninth front-layer interconnection layers FL2 to FL9 stacked on the first front-layer interconnection layer FL1 in which the output pin OP is disposed. The plurality of first to eighth block regions BA1 to BA8 may be defined for the other second to ninth front-layer interconnection layers FL2 to FL9 stacked on the first front-layer interconnection layer FL1, respectively, and accordingly, a lens region LA in which only insulating layers are disposed without interconnections 505 may be positioned on at least a partial region of the output pin OP, and an optical signal irradiated from an external entity may reach the output pin OP through the lens region LA and may be reflected.

Referring to FIG. 11B, in the first direction, the output pin OP may have a first pin width WP1, and the lens region LA may have a first lens width WL1. Referring to FIG. 11C, in the second direction, the output pin OP may have a second pin width WP2, and the lens region LA may have a second lens width WL2. The first pin width WL1 may be shorter (narrower) than the second pin width WL2, and the first lens width WL1 may be shorter than the second lens width WL2. Accordingly, the lens region LA may have a shape corresponding to the output pin OP. In addition, in an example embodiment described with reference to FIGS. 11A to 11C, the lens region LA may have a width smaller (narrower) than that of the output pin OP in the first direction and the second direction.

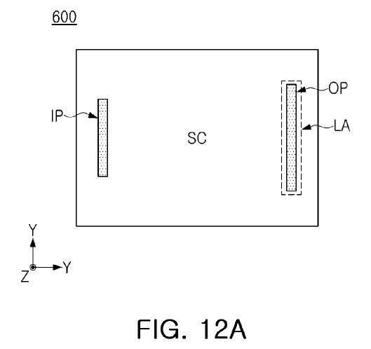

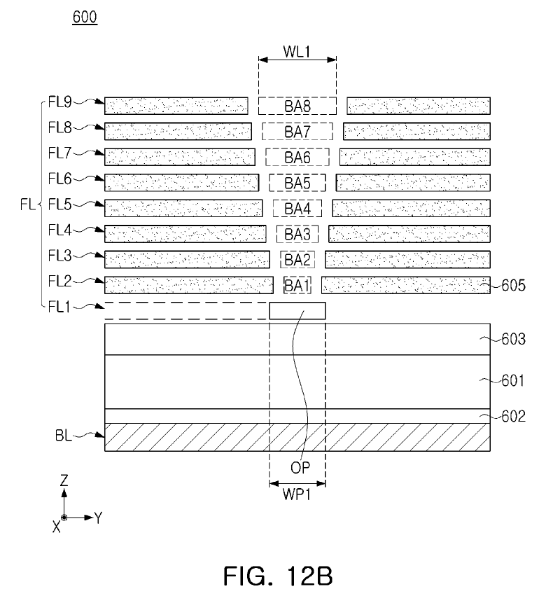

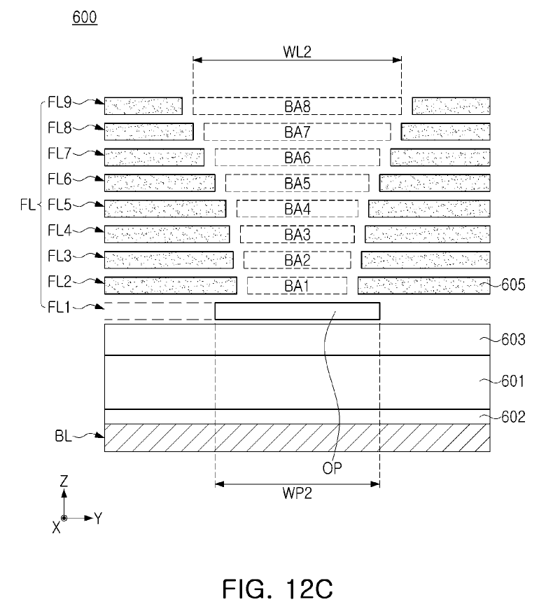

FIGS. 12A to 12C are diagrams illustrating a lens region included in a semiconductor device, according to an example embodiment. A semiconductor device 600 of FIG. 12A may include and/or may be similar in many respects to the semiconductor device 30, the semiconductor device 100, the semiconductor device 200, the semiconductor device 200A, the semiconductor device 300, the semiconductor device 400, and the semiconductor device 500 described above with reference to FIGS. 3 to 11C, and may include additional features not mentioned above. Consequently, repeated descriptions of the semiconductor device 600 described above with reference to FIGS. 3 to 11C may be omitted for the sake of brevity.

Referring to FIG. 12A, the semiconductor device 600, according to an example embodiment, may include a standard cell SC. The standard cell SC may be a target standard cell including a target pin for performing a monitoring operation of isolating a fault after a wafer including the semiconductor device 500 is fab-out. For example, the target pin may be an output pin OP, and a lens region LA for performing the monitoring operation may be formed on the output pin OP during the process of manufacturing a semiconductor device 600.

FIG. 12B is a cross-sectional diagram illustrating a lens region LA in the first direction (X-axis direction), and FIG. 12C may be a cross-sectional diagram illustrating a lens region LA in the second direction (Y-axis direction). Referring to FIGS. 12B and 12C, the semiconductor device 600 may include a semiconductor substrate 601, an element region 603, a substrate insulating layer 602, a front-layer interconnection region FL and a back-layer interconnection region BL. The element region 603, the substrate insulating layer 602, the front-layer interconnection region FL and the back-layer interconnection region BL may be understood by referring to the example embodiment described above with respect to FIGS. 11B and 11C.

In an example embodiment illustrated in FIGS. 12B and 12C, a plurality of block regions (e.g., a first block region BA1, a second block region BA2, a third block region BA3, a fourth block region BA4, a five block region BA5, a sixth block region BA6, a seventh block region BA7, and an eighth block region BA8) defined on an output pin OP may be defined to have different sizes depending on levels in the third direction (Z-axis direction). Referring to FIG. 12B, the first block region BA1 closest to the output pin OP may have the smallest (narrowest) width in the first direction, and the eighth block region BA8 farthest from the output pin OP may have the largest (widest) width in the first direction. In addition, as illustrated in FIG. 12C, the first block region BA1 closest to the output pin OP may have the smallest width in the second direction, and the eighth block region BA8 farthest from the output pin OP may have the largest width in the second direction. Accordingly, the lens region disposed on the output pin OP may have a tapered shape having a width decreasing toward the semiconductor substrate 601 in the third direction.

Referring to FIG. 12B, in the first direction, the output pin OP may have the first pin width WP1, and the lens region LA may have the first lens width WL1. Referring to FIG. 12C, in the second direction, the output pin OP may have the second pin width WP2, and the lens region LA may have the second lens width WL2. The first pin width WL1 may be shorter than the second pin width WL2, and the first lens width WL1 may be shorter than the second lens width WL2. Accordingly, the lens region LA may have a shape corresponding to the output pin OP.

In an example embodiment, in the ninth front-layer interconnection layer FL9 positioned at an uppermost end of the front-layer interconnection region FL, the lens region LA may have an area larger than an area of the output pin OP. For example, the first lens width WL1 may be larger than the first pin width WP1, and the second lens width WL2 may be larger than the second pin width WP2.

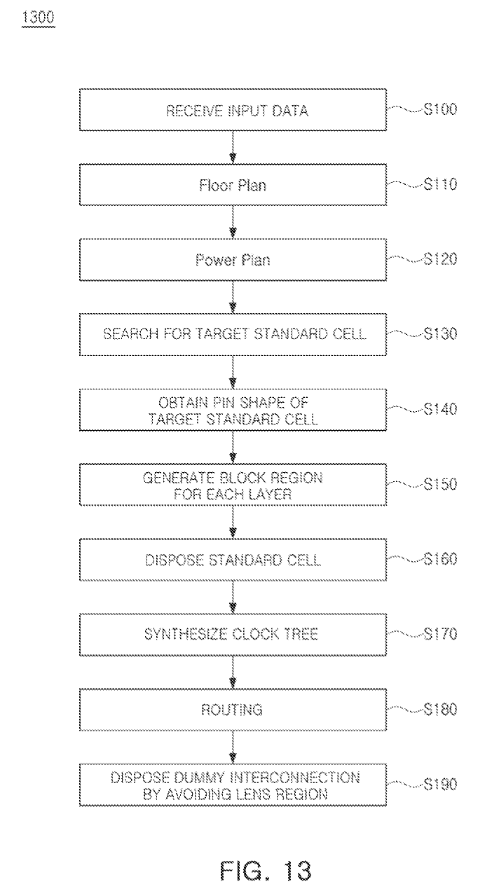

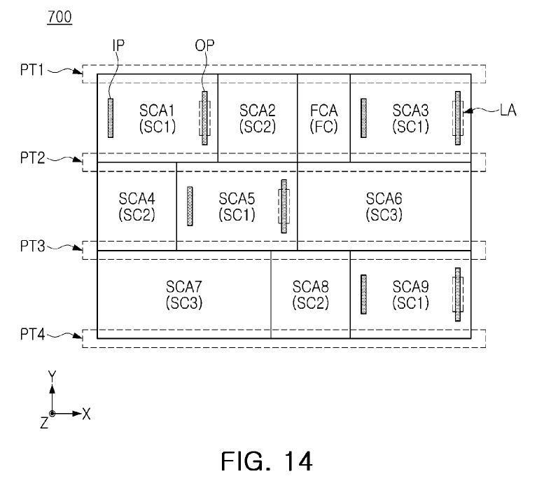

FIGS. 13 and 14 are diagrams illustrating a process of designing a semiconductor device, according to an example embodiment.

Referring to FIG. 13, a method 1300 of designing a semiconductor device, according to an example embodiment, may include receiving input data (operation S100). The input data may include register transfer level (RTL) data including information about an integrated circuit. The RTL data may define a function of the semiconductor device and may include a code represented in a language such as, but not limited to, very high speed integrated circuit (VHSIC) hardware description language (VHDL), Verilog™, or the like.

A floor plan based on the input data may be executed (operation S110). In the floor plan, a logically designed schematic circuit may be physically designed. The information of arrangement of gates included in the semiconductor device may be determined by the floor plan, In operation S110, a site-row, which may be a standard cell region for disposing standard cells stored in a standard cell library according to a predefined design rule, and a routing track, in which a signal interconnection for connecting standard cells to each other is disposed, may be generated.

The method 1300 may execute a power plan operation in operation S120, in which the arrangement of power interconnections supplying power voltages needed for operation of the semiconductor device may be determined. As described above, in a process of designing a semiconductor device, according to an example embodiment, a routing track for disposing signal interconnections on a first surface of a semiconductor substrate may be generated, and a track for disposing power interconnections on a second surface of a semiconductor substrate opposing the first surface may be generated.

A target standard cell may be searched for among standard cells stored in a standard cell library in operation S130. The target standard cell searched for in operation S130 may be a standard cell including a target pin for which a fault is isolated using an optical signal and an electron beam signal in a monitoring operation of isolating a fault after a wafer is fab-out. For example, the target standard cell may be selected from among standard cells providing a sequential logic circuit. When the target standard cell is searched, the shape of the target pin may be obtained from the target standard cell in operation S140.

When the shape of the target pin is obtained from the target standard cell, a block region may be generated for each of layers to be disposed on the target pin (operation S150). The block region generated in operation S150 may be defined for each of the front-layer interconnection layers to be disposed on the target pin as described above with reference to FIGS. 11A to 11C and FIGS. 12A to 12C. In operation S150, the block region may be generated as a region in which a signal interconnection and a dummy interconnection may not be disposed, and accordingly, only insulating layers may be positioned on the target pin after a wafer is fab-out.

A shape of the block region may be determined with reference to a shape of the target pin obtained in the S140 operation. For example, when the target pin has a shape elongated in a specific direction as described with reference to FIGS. 11A to 11C and 12A to 12C, the block region may also have a shape elongated in the same direction. However, an area of the block region may be smaller than an area of the target pin. In an example embodiment, a block region may be generated with a minimum area needed to irradiate an optical signal to the target pin in a monitoring operation for fault isolation.

Thereafter, the standard cells may be disposed according to the site-row determined in the floor plan of the operation S110 (operation S160). In an example embodiment, each of the standard cells may be disposed to correspond to a shortest interconnection path searched for by the design tool. When the standard cells are disposed, a clock tree may be synthesized (operation S170), and thereafter, a routing operation may be executed (operation S180). In the routing operation, signal interconnections connecting the standard cells and power interconnections connected to at least a portion of the standard cells may be disposed. In an example embodiment, the signal interconnections may be disposed on a first surface of the semiconductor substrate, and the power interconnections may be disposed on a second surface of the semiconductor substrate.

The method 1300 may include disposing a dummy interconnection in a region in which signal interconnections and power interconnections are not disposed (operation S190). The dummy interconnection may be disposed to avoid a lens region defined by a combination of block regions generated in operation S150. The block region may be generated such that the signal interconnection and also the dummy interconnection may not be disposed, and accordingly, in operation S190, the dummy interconnection may be disposed to avoid the lens region.

In an example embodiment described with reference to FIG. 13, a target standard cell may be searched for in a standard cell library including standard cells (operation S130), a shape of a target pin may be obtained from the searched target standard cell (operation S140), and a block region may be generated such that the signal interconnection and dummy interconnection may not be disposed on the target pin (operation S150). As for a target standard cell searched for in the standard cell library, a block region may be generated on the target pin regardless of the position in which the target standard cell is disposed according to the floor plan. Accordingly, a lens region may be formed on the target pin of the target standard cell searched in operation S130.

FIG. 14 is a diagram illustrating a semiconductor device 700 manufactured by a design operation, according to the example embodiment described with reference to FIG. 13. A semiconductor device 700 of FIG. 14 may include and/or may be similar in many respects to the semiconductor device 30, the semiconductor device 100, the semiconductor device 200, the semiconductor device 200A, the semiconductor device 300, the semiconductor device 400, the semiconductor device 500, and the semiconductor device 600 described above with reference to FIGS. 3 to 12C, and may include additional features not mentioned above. Consequently, repeated descriptions of the semiconductor device 700 described above with reference to FIGS. 3 to 12C may be omitted for the sake of brevity.

Referring to FIGS. 13 and 14 together, a plurality of first to ninth standard cell regions SCA1 to SCA9 and filler cell region FCA may be defined in the floor plan of operation S110, and the plurality of first to third standard cells SC1 to SC3 may be disposed in operation S160. In a routing operation in operation S180, signal interconnections may be disposed instead of power interconnections in a plurality of first to fourth tracks PT1 to PT4 extending in the first direction (X-axis direction) along a boundary between the plurality of first to ninth standard cell regions SCA1 to SCA9. In an example embodiment, among the plurality of signal interconnections included in the semiconductor device 700, at least a portion of the lowermost signal interconnections disposed at a lowermost level closest to the semiconductor substrate may be disposed along the plurality of first to fourth tracks PT1 to PT4.

In an example embodiment, in operation S130 executed prior to the arrangement of the plurality of first to third standard cells SC1 to SC3, a target standard cell among the plurality of first to third standard cells SC1 to SC3 to be disposed may be searched for. In the example embodiment illustrated in FIG. 14, the target standard cell may be the first standard cell SC1. Once the target standard cell is searched for, the shape of the target pin included in the target standard cell may be obtained in operation S140. In the example embodiment illustrated in FIG. 14, the target pin may be the output pin OP of the first standard cell SC1. According to the shape of the obtained output pin OP, a block region may be defined for each layer on the output pin OP as in operation S150 described above, and a lens region LA may be disposed on the output pin OP by the block region.

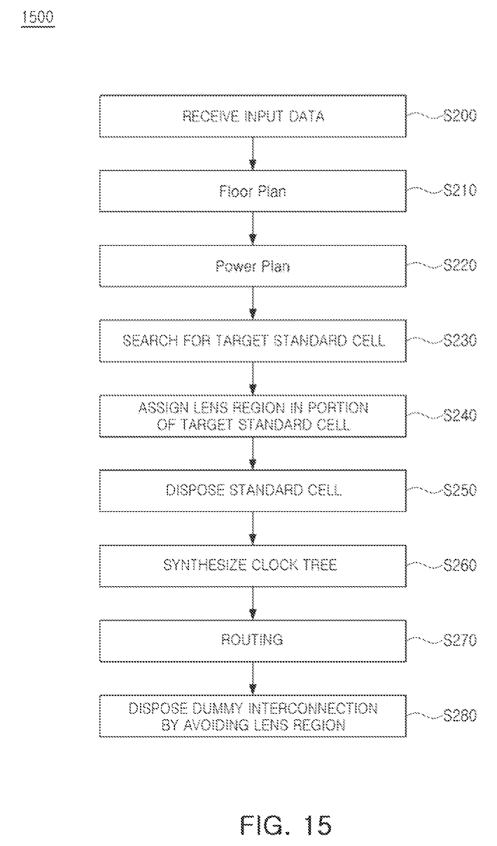

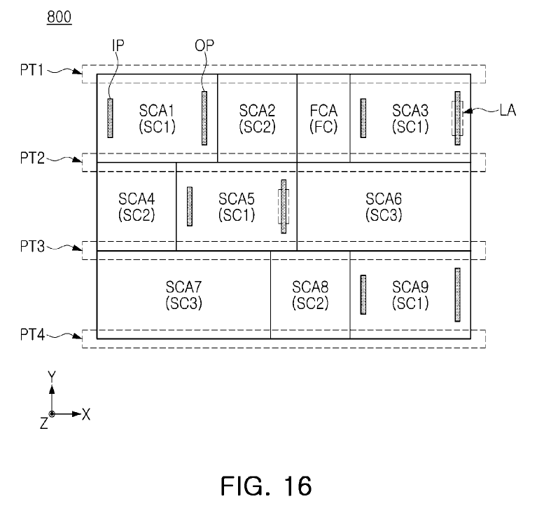

FIGS. 15 and 16 are diagrams illustrating a process of designing a semiconductor device, according to an example embodiment.

Referring to FIG. 15, a process 1500 of designing a semiconductor device, according to an example embodiment, may include receiving input data (operation S200). The input data may be and/or may include RTL data including a code defining the function of the semiconductor device and represented in languages such as, but not limited to, VHDL or Verilog™ as described above.

The process 1500 may include executing a floor plan based on the input data (operation S210), positions of standard cell regions in which standard cells stored in the standard cell library may be disposed, and routing tracks may be determined. Thereafter, a power plan operation may be executed (operation S220), and arrangements of power interconnections supplying power voltages necessary for operation of the semiconductor device may be determined. In the process 1500 of designing a semiconductor device, according to an example embodiment, a routing track for disposing signal interconnections may be generated on a first surface of a semiconductor substrate, and a track for disposing power interconnections may be generated on a second surface of a semiconductor substrate opposing the first surface.

In operation S230, the target standard cell may be searched for among the standard cells stored in the standard cell library. The target standard cell searched for in operation S230 may be a standard cell including a target pin for which a fault is to be isolated using an optical signal and an electron beam signal in a monitoring operation of isolating a fault after a wafer is fab-out. For example, the target standard cell may provide a sequential logic circuit.

In an example embodiment described with reference to FIG. 15, when the target standard cell is searched for, a lens region may be assigned only to a portion of the target standard cells to be disposed in the standard cell regions according to the floor plan (operation S240). In operation S240, the shape of the target pin included in the target standard cell may be obtained, and a block region may be generated for each of the layers disposed on the target pin by referring to the shape of the target pin, thereby assigning the lens region.

In an example embodiment described with reference to FIG. 15, each of the standard cells stored in the standard cell library may not include a block region for assigning a lens region. Instead, based on a position in which a target standard cell searched for in operation S230 is disposed according to a floor plan, a lens region may be assigned to at least a portion of the target standard cell. For example, library exchange format (LEF) data in which a lens region is assigned to a target standard cell may be generated in operation S240 and may be added to the standard cell library.

Thereafter, the standard cells may be disposed according to the site-row determined in the floor plan in operation S210 (operation S250). Each of the standard cells may be disposed to correspond to a shortest interconnection path searched for by the design tool. When the standard cells are disposed, a clock tree may be synthesized (operation S260), and thereafter, a routing operation may be executed (operation S270). In a routing operation, signal interconnections connecting standard cells, and power interconnections connecting at least a portion of the standard cells may be disposed. In an example embodiment, the signal interconnections may be disposed on a first surface of a semiconductor substrate, and the power interconnections may be disposed on a second surface of the semiconductor substrate.

Thereafter, a dummy interconnection may be disposed by avoiding the lens region (operation S280). The dummy interconnection may be disposed in a region in which the signal interconnection and the power interconnection are not disposed, and may be disposed by avoiding the lens region assigned to a portion of the target standard cells in operation S240.

In an example embodiment described with reference to FIG. 15, a target standard cell may be searched for in a standard cell library including standard cells (operation S230), and a lens region may be assigned only to a portion of the target standard cells disposed in a specific position among the searched target standard cells (operation S240). Accordingly, depending on the position in which the target standard cell searched in operation S230 is disposed, a lens region may or may not be present on the target pin.

FIG. 16 is a diagram illustrating a semiconductor device 800 manufactured by a design operation, according to an example embodiment described with reference to FIG. 15. A semiconductor device 800 of FIG. 16 may include and/or may be similar in many respects to the semiconductor device 30, the semiconductor device 100, the semiconductor device 200, the semiconductor device 200A, the semiconductor device 300, the semiconductor device 400, the semiconductor device 500, the semiconductor device 600, and the semiconductor device 700 described above with reference to FIGS. 3 to 14, and may include additional features not mentioned above. Consequently, repeated descriptions of the semiconductor device 700 described above with reference to FIGS. 3 to 14 may be omitted for the sake of brevity.

Referring to FIGS. 15 and 16 together, in a floor plan of operation S210, a plurality of first to ninth standard cell regions SCA1 to SCA9 and a filler cell region FCA may be defined, and in operation S250, the plurality of first to third standard cells SC1 to SC3 may be disposed. In a routing operation of operation S270, signal interconnections may be disposed instead of power interconnections in the plurality of first to fourth tracks PT1 to PT4 extending in the first direction (X-axis direction) along a boundary between the plurality of first to ninth standard cell regions SCA1 to SCA9. In an example embodiment, among the plurality of signal interconnections included in the semiconductor device 700, at least a portion of the lowermost signal interconnections disposed at a lowermost level closest to the semiconductor substrate may be disposed along a plurality of first to fourth tracks PT1 to PT4.

In an example embodiment, in operation S230 executed prior to arrangement of the plurality of first to third standard cells SC1 to SC3, a target standard cell among the plurality of first to third standard cells SC1 to SC3 to be disposed may be searched for. In an example embodiment illustrated in FIG. 16, the target standard cell may be the first standard cell SC1. When the first standard cell SC1 is searched for as the target standard cell, a portion of the first standard cells SC1 to which the lens region LA is assigned may be selected depending on a position in which the first standard cell SC1 is disposed.

Referring to FIG. 16, the lens region LA may be assigned to the output pin OP of the first standard cell SC1 disposed in the third standard cell region SCA3 and the third standard cell region SCA5. The lens region LA may not be assigned to the output pin OP of the first standard cell SC1 disposed in the first standard cell region SCA1 and the ninth standard cell region SCA9. Similarly, as for the same type of standard cells disposed in the semiconductor device 800, the cell may be selected as a target standard cell or may not be selected as a target standard cell depending on a position in which the cells are disposed in the first direction and the second direction. A standard cell selected as a target standard cell may include block regions in which the arrangement of interconnections on the target pin is excluded, and accordingly, a lens region LA may be present on the target pin. An input pin and an output pin of a standard cell not selected as a target standard cell may not be selected as target pins such that the pins may not include the lens region LA.

According to the aforementioned example embodiments, in a semiconductor device having a structure in which signal interconnections and power interconnections are isolated on both surfaces of the semiconductor substrate, at least one lens region in which interconnections are not disposed may be defined on one surface of the semiconductor substrate. The lens region may be defined on a target pin included in a target standard cell of at least a portion of standard cells, and the target pin may be an input pin and/or an output pin of the target standard cell. Only insulating layers, rather than interconnections, may be disposed on the target pin by the lens region, and optical fault isolation for the target pin may be executed through the lens region. Accordingly, in a semiconductor device having a structure in which signal interconnections and power interconnections are isolated on both surfaces of the semiconductor substrate, a fault isolation operation may be performed efficiently and accurately.

While the example embodiments have been illustrated and described above, it is to be apparent to those skilled in the art that modifications and variations may be made without departing from the scope of the present disclosure as defined by the appended claims.

What is claimed is:

1. A semiconductor device, comprising:
a semiconductor substrate;
a plurality of standard cells disposed in a first direction and a second direction, the first direction and the second direction being parallel to an upper surface of the semiconductor substrate;
a plurality of signal interconnections disposed in an upper insulating layer on the upper surface of the semiconductor substrate and coupled with the plurality of standard cells; and
a plurality of power interconnections disposed on a lower surface of the semiconductor substrate and coupled with at least a portion of the plurality of standard cells,
wherein at least one target standard cell from among the plurality of standard cells comprises a target pin, and
wherein a lens region comprising only the upper insulating layer is disposed on at least a partial region of the target pin in a third direction perpendicular to the upper surface of the semiconductor substrate.

2. The semiconductor device of claim 1, wherein the plurality of signal interconnections comprise lowermost interconnections disposed at a lowermost level closest to the upper surface of the semiconductor substrate, and
wherein at least a portion of the lowermost interconnections is disposed along a boundary between the plurality of standard cells extending in the first direction.

3. The semiconductor device of claim 1, wherein a width of the lens region is narrower than a width of the target pin in at least one of the first direction or the second direction.

4. The semiconductor device of claim 1, wherein a width of the lens region in at least one of the first direction or the second direction increases in a direction away from the upper surface of the semiconductor substrate along the third direction.

5. The semiconductor device of claim 1, wherein, at an upper surface of the upper insulating layer, the lens region has a first lens width in the first direction and a second lens width in the second direction, and
wherein the second lens width is different from the first lens width.

6. The semiconductor device of claim 5, wherein the target pin has a first pin width in the first direction and a second pin width in the second direction, and
wherein the second pin width is different from the first pin width.

7. The semiconductor device of claim 6, wherein the first pin width is narrower than the second pin width, and
wherein the first lens width is narrower than the second lens width.

8. The semiconductor device of claim 1, wherein each of the at least one target standard cell provides a flip-flop circuit.

9. The semiconductor device of claim 1, wherein the lens region comprises:
a first lens layer disposed on the upper surface of the semiconductor substrate; and
a second lens layer stacked on the first lens layer in the third direction, and
wherein a permittivity of the first lens layer is higher than a permittivity of the second lens layer.

10. The semiconductor device of claim 9, wherein the lens region further comprises a third lens layer stacked on the second lens layer in the third direction, and
wherein a permittivity of the third lens layer is higher than the permittivity of the second lens layer.

11. The semiconductor device of claim 9, wherein each of the at least one target standard cell provides a sequential logic circuit, and
wherein the target pin is at least one of an input pin or an output pin of the sequential logic circuit.

12. A semiconductor device, comprising:
a semiconductor substrate;
a plurality of standard cells disposed in a first direction and a second direction, the first direction and the second direction being parallel to an upper surface of the semiconductor substrate;
a plurality of signal interconnections disposed on the upper surface of the semiconductor substrate and coupled with the plurality of standard cells;
a plurality of power interconnections disposed on a lower surface of the semiconductor substrate and coupled with at least a portion of the plurality of standard cells; and
a plurality of dummy interconnections disposed on the upper surface of the semiconductor substrate and isolated from the plurality of standard cells,
wherein the plurality of standard cells comprise at least one target standard cell,
wherein a target pin is at least one of an input pin or an output pin of the at least one target standard cell, and
wherein at least a partial region of the target pin at least partially overlaps a lens region optically exposing the target pin in a third direction perpendicular to the upper surface of the semiconductor substrate.

13. The semiconductor device of claim 12, wherein each of the at least one target standard cell provides a sequential logic circuit comprised in a scan chain circuit.

14. The semiconductor device of claim 12, wherein the lens region has a tapered shape, and
wherein an area of the tapered shape decreases toward the target pin along the third direction.

15. The semiconductor device of claim 12, wherein the lens region comprises a plurality of lens layers stacked on each other, and
wherein at least a portion of the plurality of lens layers comprises materials having different permittivities.

16. The semiconductor device of claim 15, wherein each of the plurality of lens layers comprises a low-k material having a permittivity lower than a permittivity of silicon oxide (SiO).

17. The semiconductor device of claim 12, wherein a remaining region of the target pin at least partially overlaps at least one of the plurality of signal interconnections or the plurality of dummy interconnections in the third direction.

18. The semiconductor device of claim 12, wherein a shape of the lens region corresponds to a shape of the target pin.

19. A semiconductor device, comprising:
a semiconductor substrate;
an element region comprising:
a plurality of semiconductor elements formed on a first surface of the semiconductor substrate; and
a plurality of contact structures coupled with the plurality of semiconductor elements;
a back-layer interconnection region disposed on a second surface of the semiconductor substrate opposing the first surface of the semiconductor substrate, and comprising a plurality of power interconnections coupled with at least a first portion of the plurality of contact structures by via structures at least partially penetrating the semiconductor substrate;
a front-layer interconnection region comprising:
a plurality of signal interconnections coupled with at least a second portion of the plurality of contact structures; and
a plurality of front-layer interconnection layers stacked on the first surface of the semiconductor substrate,
wherein the plurality of signal interconnections comprise at least one target pin, and
wherein each of at least a portion of the plurality of front-layer interconnection layers, positioned on the at least one target pin in a direction perpendicular to the first surface of the semiconductor substrate, comprises a block region from which the plurality of signal interconnections are excluded.

20. The semiconductor device of claim 19, wherein the element region further comprises a plurality of standard cells disposed in a first direction and a second direction,
wherein the first direction and the second direction are parallel to the first surface of the semiconductor substrate,
wherein the at least one target pin is comprised in at least one target standard cell from among the plurality of standard cells, and
wherein remaining standard cells from among the plurality of standard cells providing a same circuit as the at least one target standard cell and disposed in a position different from the at least one target standard cell in at least one of the first direction or the second direction, do not comprise the at least one target pin.
